(19) United States
(12) Patent Application Publication
(10) Pub. No.: US 2025/0374519 A1
(43) Pub. Date: Dec. 4, 2025

(54) SEMICONDUCTOR DEVICE AND METHOD OF MANUFACTURING THE SAME

(71) Applicant: Samsung Electronics Co., Ltd., Suwon-si (KR)

(72) Inventor: Hyeon-Woo JANG, Suwon-si (KR)

(73) Assignee: Samsung Electronics Co., Ltd., Suwon-si (KR)

(21) Appl. No.: 18/914,542

(22) Filed: Oct. 14, 2024

(30) Foreign Application Priority Data
May 28, 2024 (KR) 10-2024-0069587

(51) Int. Cl. H10B 12/00; H01L 23/532

(52) U.S. Cl. CPC H10B 12/315; H01L 23/53266; H01L 23/5329; H10B 12/0335; H10B 12/482; H10B 12/50

(57) ABSTRACT

A semiconductor device may include a substrate including a cell array area and a peripheral area, a plurality of bit lines in the cell array area, a plurality of insulating capping structures covering the plurality of bit lines, a plurality of bit line spacers surrounding the plurality of bit lines, a cell pad structure between a pair of adjacent bit lines among the plurality of bit lines, a landing pad on the cell pad structure and including a conductive barrier film and a landing pad conductive layer, and an insulating pattern covering at least a portion of the landing pad. The insulating pattern may be in contact with the conductive barrier film.

### CROSS-REFERENCE TO RELATED APPLICATION

This application claims the benefit of Korean Patent Application No. 10-2024-0069587 filed on May 28, 2024, in the Korean Intellectual Property Office, the entire disclosure of which is incorporated herein by reference for all purposes.

### BACKGROUND

### 1. Field

The present disclosure relates to a semiconductor device and a method of manufacturing the semiconductor device.

### 2. Description of the Related Art

Semiconductors may include tiny circuit patterns on a nanometer scale that may be invisible to the naked eye. To create these tiny patterns, it may be essential to precisely define which portions to etch and which to retain. This process is known as photolithography in the semiconductor process. Lithography refers to a method by which a design is etched onto a stone plate and then printed. Because the design is printed, the same shape may be replicated repeatedly. In the semiconductor process, these identical shapes may need to be printed without any errors even in tens of nanometers. “Photo” indicates that a lithographic technique is implemented using light. The design is etched onto a plate called a mask, and light is shone through the mask so that only the areas where light passes through are focused onto a wafer through an optical system lens, creating a small pattern printed on the wafer. The photoresist coating on the wafer undergoes a chemical reaction only in the areas exposed to light, resulting in a difference in solubility between the exposed and unexposed areas. Subsequently, the develop process allows for selective etching of the desired pattern areas in the etch process or selective injection of implants in the implant process.

Due to characteristics such as miniaturization, multifunctionality, and/or lower manufacturing costs, semiconductor devices are gaining prominence as key components in the electronics industry. However, as the electronics industry continues to highly advance, the trend towards higher integration of semiconductor devices is intensifying. To achieve higher integration, the line widths of patterns in semiconductor devices are being progressively reduced. Recently, however, the miniaturization of these patterns has required new exposure technologies and/or high-cost exposure techniques, making it increasingly challenging to achieve higher integration in semiconductor devices. Accordingly, a great deal of research is currently being conducted on new integration technologies. For example, in dynamic random-access memory (DRAM) memory devices, structures in which word lines are embedded within a semiconductor substrate are being explored.

The above information may be presented as the related art to help with the understanding of the disclosure. No arguments or decisions are made as to whether any of the above is applicable as a prior art related to the disclosure.

### SUMMARY

The present disclosure relates to a semiconductor device and a method of manufacturing the semiconductor device.

According to an embodiment, a semiconductor device may include a substrate including a cell array area and a peripheral area; a plurality of bit lines in the cell array area; a plurality of insulating capping structures covering the plurality of bit lines; a plurality of bit line spacers surrounding the plurality of bit lines; a cell pad structure between a pair of adjacent bit lines among the plurality of bit lines; a landing pad on the cell pad structure, the landing pad including a conductive barrier film and a landing pad conductive layer; and an insulating pattern covering at least a portion of the landing pad, the insulating pattern being in contact with the conductive barrier film.

In some embodiments, a bit line among the plurality of bit lines and the conductive barrier film may be opposite to each other with the insulating pattern therebetween.

In some embodiments, a bit line among the plurality of bit lines and the conductive barrier film may be spaced apart from each other in a direction perpendicular to a stacking direction of the bit line and a corresponding one of the plurality of insulating capping structures.

In some embodiments, the insulating pattern may be in contact with a corresponding one of the plurality of insulating capping structures.

In some embodiments, the conductive barrier film may include a barrier body in contact with the cell pad structure; and a barrier head connected to the barrier body.

In some embodiments, the landing pad conductive layer may be between the insulating pattern and the barrier head.

In some embodiments, at least a portion of the insulating pattern may be between the bit line spacer and the conductive barrier film.

In some embodiments, the bit line spacer and the conductive barrier film may be spaced apart from each other.

In some embodiments, the conductive barrier film may include a titanium nitride film or a tantalum nitride film.

In some embodiments, the insulating pattern may include a silicon nitride film, a silicon oxide film, a silicon oxynitride film, a silicon carbonitride film, or a porous film.

In some embodiments, at least a portion of the insulating pattern may be in the cell pad structure.

In some embodiments, an upper end portion of the cell pad structure may have an asymmetrical shape.

In some embodiments, based on a direction perpendicular to a stacking direction of the insulating capping structure and a bit line among the plurality of bit lines, a distance between the bit line and the cell pad structure may be less than a distance between the bit line and the conductive barrier film.

In some embodiments, a width of the insulating pattern may decrease toward the cell pad structure.

According to an embodiment, a method of manufacturing a semiconductor device may include forming a cell pad structure, forming a bit line at a position spaced apart from the cell pad structure, forming a landing pad including a conductive barrier film and a landing pad conductive layer on the cell pad structure, and forming an insulating pattern covering the landing pad. The forming the insulating pattern may include removing least a portion of the conductive barrier film.

In some embodiments, the bit line and the conductive barrier film may be opposite each other with the insulating pattern therebetween.

In some embodiments, the forming the insulating pattern may include inserting a portion of the insulating pattern in the cell pad structure.

In some embodiments, the forming the insulating pattern may include removing a portion of the bit line.

According to an embodiment, a semiconductor device may include a substrate including a cell array area and a peripheral area; a plurality of bit lines in the cell array area; a plurality of insulating capping structures covering the plurality of bit lines; a cell pad structure between a pair of adjacent bit lines among the plurality of bit lines; a landing pad in the cell pad structure, the landing pad including a conductive barrier film and a landing pad conductive layer; and an insulating pattern covering at least a portion of the landing pad and overlapping the cell pad structure in a direction perpendicular to a stacking direction of the plurality of bit lines and the plurality of insulating capping structures.

A semiconductor device and a method of manufacturing the semiconductor device according to the present disclosure may limit and/or prevent signal leakage by removing a portion of a conductive barrier film, filling the removed portion with an insulating pattern, and positioning the insulating pattern between a bit line and the conductive barrier film.

A semiconductor device and a method of manufacturing the semiconductor device according to the present disclosure may increase the distance between a bit line and a conductive barrier film by removing a portion of the conductive barrier film and filling the removed portion with an insulating pattern.

### BRIEF DESCRIPTION OF THE DRAWINGS

The foregoing and other aspects, features, and advantages of certain embodiments in the disclosure will become apparent from the following detailed description with reference to the accompanying drawings.

FIG. 1 is a schematic view illustrating a semiconductor device according to an embodiment.

FIG. 2 is a layout view illustrating the semiconductor device according to example embodiments.

FIG. 3 is an enlarged layout view of a portion A of FIG. 2.

FIG. 4 is a cross-sectional view taken along a line B1-B1′ of FIG. 3.

FIG. 5 is a cross-sectional view taken along a line B2-B2′ of FIG. 3.

FIG. 6 is an enlarged cross-sectional view of a portion CX1 of FIG. 4.

FIGS. 7 to 16 are cross-sectional views of the semiconductor device according to example embodiments and illustrate a method of manufacturing the semiconductor device.

FIG. 17 is a flowchart illustrating a method of manufacturing a semiconductor memory device, according to an embodiment.

FIGS. 18 and 19 are cross-sectional views of the semiconductor device according to example embodiments and illustrate the method of manufacturing the semiconductor device.

### DETAILED DESCRIPTION

Hereinafter, embodiments will be described in detail with reference to the accompanying drawings. When describing the embodiments with reference to the accompanying drawings, like reference numerals refer to like elements and a repeated description related thereto will be omitted.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

The notion that elements are “substantially the same” may indicate that the element may be completely the same and may also indicate that the elements may be determined to be the same in consideration of errors or deviations occurring during a process.

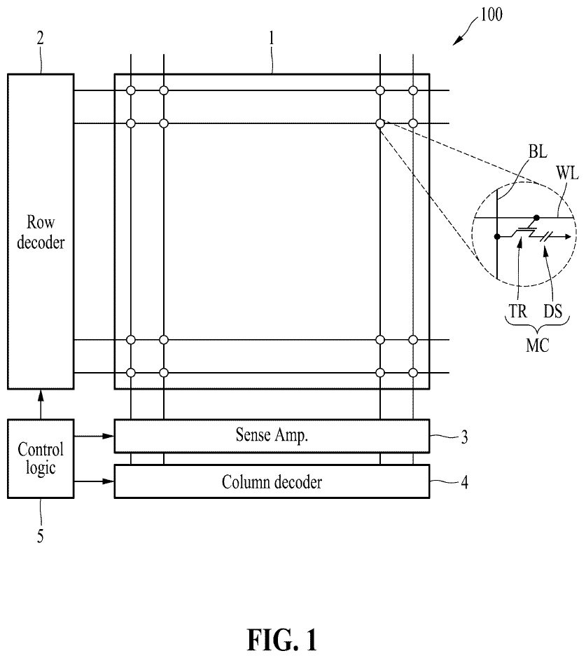

FIG. 1 is a schematic view of a semiconductor device according to an embodiment.

A semiconductor device 100 may include a memory cell array 1, a row decoder 2, a sense amplifier 3, a column decoder 4, and a control logic 5. For example, the semiconductor device 100 may be a memory device and may be implemented as a dynamic random access memory (DRAM) device.

The memory cell array 1 may include a plurality of memory cells MC arranged two-dimensionally or three-dimensionally. For example, the memory cell array 1 may be positioned on one surface of a substrate, and the plane of the memory cell array 1 and the plane of the substrate may be parallel to each other. Each of the plurality of memory cells MC may be connected to a word line WL and a bit line BL that intersect with each other.

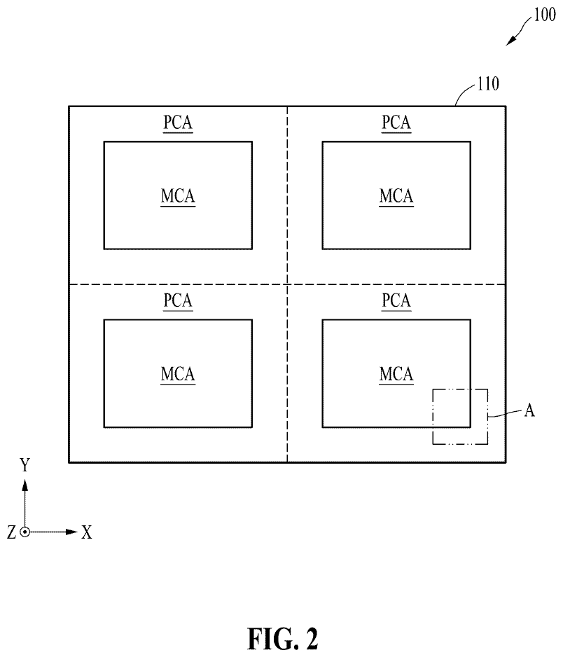

Each of the plurality of memory cells MC may include a selection element TR and a data storage element DS. The selection element TR and the data storage element DS may be electrically connected to each other. The selection element TR may be connected to both the word line WL and the bit line BL. For example, the selection element TR may be provided at a position at which the word line WL and the bit line BL intersect with each other. The selection element TR may include a field-effect transistor. The data storage element DS may include a capacitor, a magnetic tunnel junction pattern, or a variable resistor. For example, a gate terminal of a transistor, which is the selection element TR, may be connected to the word line WL, and a source terminal or a drain terminal of the transistor may be connected to the bit line BL or the data storage element DS. An example of a connection structure between the selection element TR, the data storage element DS, the word line WL, and the bit line BL of each of the plurality of memory cells MC in the memory cell array 1 is described with reference to FIG. 2.

The selection element TR of each of the memory cells may include a vertical channel transistor (VCT). The lengthwise direction of a channel of the VCT may be a direction perpendicular to one surface (e.g., the upper surface) of the substrate.

The row decoder 2 may decode an address input from the outside of the semiconductor device 100. The row decoder 2 may select one of the word lines WL of the memory cell array 1 using a result of decoding the address. The decoding result (e.g., a decoded address) from the row decoder 2 may be provided to a row driver (not shown). The row driver may provide desired and/or alternatively predetermined voltages to each of the selected word line WL and non-selected word lines in response to the control by control circuits.

The sense amplifier 3 may detect, amplify, and output the voltage difference between a reference bit line and the bit line BL selected according to an address decoded by the column decoder 4.

The column decoder 4 may provide a data transmission path between the sense amplifier 3 and an external device (e.g., a memory controller). The column decoder 4 may select one of the bit lines BL by decoding an address input from the outside.

The control logic 5 may generate a control signal for controlling an operation of writing or reading data for a corresponding memory cell in the memory cell array 1.

It is illustrated that the row decoder 2, the sense amplifier 3, the column decoder 4, and the control logic 5 are placed around the memory cell array 1, but embodiments are not limited thereto. A peripheral circuit including the row decoder 2, the sense amplifier 3, the column decoder 4, and the control logic 5 may be disposed on a plane that is different from the plane on which the memory cell array 1 is disposed. The peripheral circuit may be disposed on the upper portion or lower portion of the memory cell array 1 through a cell over peri (COP) structure. For example, a peripheral circuit structure may be provided on the substrate, and the memory cell array 1 may be provided on the peripheral circuit. In another example, the peripheral circuit may be provided on a first substrate and the memory cell array 1 may be provided on a second substrate. The first substrate and the second substrate may face each other.

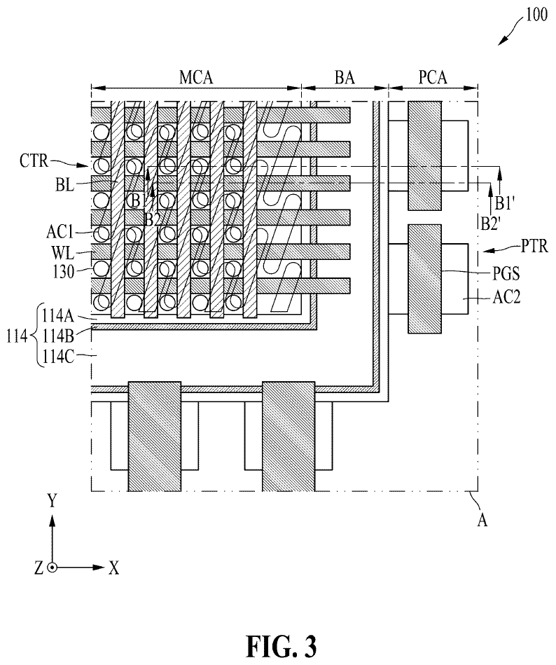

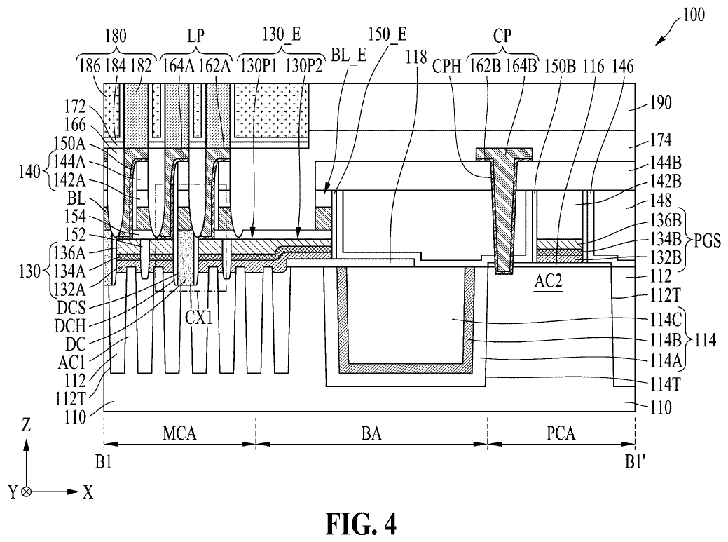

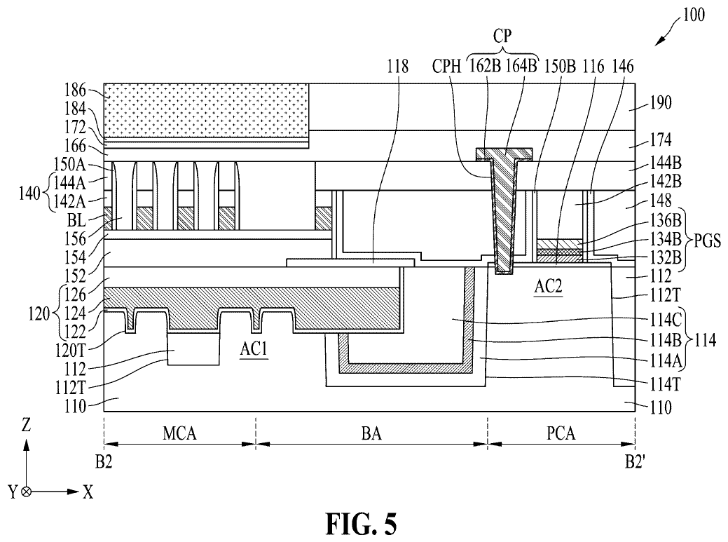

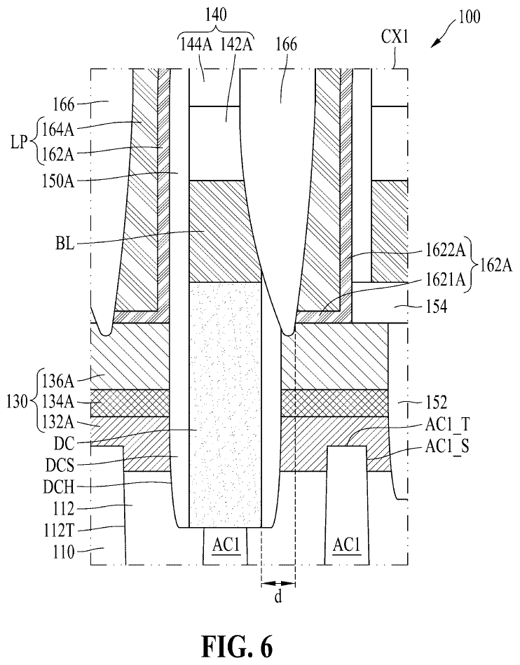

FIG. 2 is a layout view illustrating the semiconductor device according to example embodiments. FIG. 3 is an enlarged layout view of a portion A of FIG. 2. FIG. 4 is a cross-sectional view taken along a line B1-B1′ of FIG. 3. FIG. 5 is a cross-sectional view taken along a line B2-B2′ of FIG. 3. FIG. 6 is an enlarged cross-sectional view of a portion CX1 of FIG. 4.

Referring to FIGS. 2 to 6, the semiconductor device 100 may include a substrate 110 including a cell array area MCA and a peripheral circuit area PCA. The cell array area MCA may be a memory cell area (e.g., the memory cell array 1 of FIG. 1) of a DRAM element, and the peripheral circuit area PCA may be a core area or a peripheral circuit area of the DRAM element. For example, the cell array area MCA may include a cell transistor CTR and a capacitor structure 180 connected to the cell transistor CTR, and the peripheral circuit area PCA may include a peripheral circuit transistor PTR for transmitting a signal and/or power to the cell transistor CTR included in the cell array area MCA. The peripheral circuit transistor PTR may be included in various circuits such as a command decoder, a control logic, an address buffer, a row decoder, a column decoder, a sense amplifier, a data input/output circuit, and the like.

An element separating trench 112T may be formed in the substrate 110, and an element separating film 112 may be formed in the element separating trench 112T. By the element separating film 112, a plurality of first active areas AC1 may be defined on the substrate 110 in the cell array area MAC and a plurality of second active areas AC2 may be defined on the substrate 110 in the peripheral circuit area PCA.

A boundary trench 114T may be formed in a boundary area BA between the cell array area MAC and the peripheral circuit area PCA, and a boundary structure 114 may be formed in the boundary trench 114T. In a plan view, the boundary trench 114T may be disposed to surround the four surfaces of the cell array area MCA. The boundary structure 114 may include a buried insulating layer 114A, an insulating liner 114B, and a gap fill insulating layer 114C disposed in the boundary trench 114T.

The buried insulating layer 114A may be disposed on the inner wall of the boundary trench 114T in a conformal way. The buried insulating layer 114A may include a silicon oxide. For example, the buried insulating layer 114A may include a silicon oxide formed by a process such as an atomic layer deposition (ALD) process, a chemical vapor deposition (CVD) process, a plasma-enhanced CVD (PECVD) process, a low pressure CVD (LPCVD) process, and the like.

The insulating liner 114B may be disposed on the inner wall of the boundary trench 114T on the buried insulating layer 114A in a conformal way. The insulating liner 114B may include a silicon nitride. For example, the insulating liner 114B may include a silicon nitride formed by a process such as an ALD process, a CVD process, a PECVD process, an LPCVD process, and the like.

The gap fill insulating layer 114C may fill the inside of the boundary trench 114T on the insulating liner 114B. The gap fill insulating layer 114C may include a silicon oxide such as tonen silazene (TOSZ), undoped silicate glass (USG), boro-phospho-silicate glass (BPSG), phosphosilicate glass (PSG), a flowable oxide (FOX), plasma enhanced deposition of tetra-ethyl-ortho-silicate (PE-TEOS), fluoride silicate glass (FSG), or the like.

Each of the plurality of first active areas AC1 may be disposed in the cell array area MCA to have a long axis in a diagonal direction with respect to a first horizontal direction X and a second horizontal direction Y The plurality of word lines WL may extend to be parallel to one another in the first horizontal direction X across the plurality of first active areas AC1. The plurality of bit lines BL may extend to be parallel to one another above the plurality of word lines WL in the second horizontal direction Y The plurality of bit lines BL may be connected to the plurality of first active areas AC1 through a direct contact DC.

A plurality of cell pad structures 130 may be formed between two adjacent bit lines BL among the plurality of bit lines BL. The plurality of cell pad structures 130 may be arranged in a row in the first horizontal direction X and the second horizontal direction Y A plurality of landing pads LP may be formed on the plurality of cell pad structures 130. The plurality of cell pad structures 130 and the plurality of landing pads LP may play a role in connecting a lower electrode 182 of a capacitor structure 180 formed on the upper portion of the plurality of bit lines BL to the first active areas AC1. Each of the plurality of landing pads LP may be disposed to partially overlap the cell pad structures 130.

The substrate 100 may include silicon such as monocrystalline silicon, polycrystalline silicon, or amorphous silicon. The substrate 110 may include at least one of Ge, SiGe, SiC, GaAs, InAs, and InP. The substrate 110 may include a conductive area such as a well doped with impurities or a structure doped with impurities. The element separating film 112 may include an oxide film or a nitride film, or a combination thereof.

In the cell array area MCA, a plurality of word line trenches 120T extending in a first direction (X direction) is disposed in the substrate 110 and a buried gate structure 120 may be disposed in the plurality of word line trenches 120T. The buried gate structure 120 may include a gate dielectric film 122, a gate electrode 124, and a capping insulating film 126 disposed in each of the plurality of word line trenches 120T. A plurality of gate electrodes 124 may respectively correspond to the plurality of word lines WL illustrated in FIG. 2.

A plurality of gate dielectric films 122 may include a silicon oxide film, a silicon nitride film, a silicon oxynitride film, an oxide/nitride/oxide (ONO) film, or a high-k dielectric film having a dielectric constant higher than that of a silicon oxide film. The plurality of gate electrodes 124 may include Ti, TiN, Ta, TaN, W, WN, TiSiN, or WSiN, or a combination thereof. A plurality of capping insulating films 126 may include a silicon oxide film, a silicon nitride film, or a silicon oxynitride film, or a combination thereof.

The plurality of word line trenches 120T may extend from the cell array area MCA to the inside of the boundary area BA, and an end portion of each of the plurality of word line trenches 120T may vertically overlap the boundary structure 114 in the boundary area BA.

In the boundary area BA, a buffer layer 118 may be formed on the substrate 110, the buried gate structure 120, and the boundary structure 114. The buffer layer 118 may include an oxide film, or a nitride film, or a combination thereof.

A plurality of direct contacts DC may be formed in a plurality of direct contact holes DCH on the substrate 110. The plurality of direct contacts DC may be connected to the plurality of first active areas AC1. The plurality of direct contacts DC may include TiN, TiSiN, W, tungsten silicide, or doped polysilicon, or a combination thereof.

A direct contact spacer DCS may be disposed on the inner wall of a direct contact hole DCH. The direct contact spacer DCS may be disposed on a lower side wall of the direct contact hole DCH and may cover the lower side of a direct contact DC.

The plurality of bit lines BL may extend to be elongated in the second horizontal direction Y on the substrate 110 and the plurality of direct contacts DC. Each of the plurality of bit lines BL may be connected to a first active area AC1 through a direct contact DC. The plurality of bit lines BL may include ruthenium (Ru), tungsten (W), cobalt (Co), titanium (Ti), or a titanium nitride (TiN), or a combination thereof.

The plurality of bit lines BL may be covered respectively by a plurality of insulating capping structures 140. The plurality of insulating capping structures 140 may extend in the second horizontal direction Y on the plurality of bit lines BL. The plurality of insulating capping structures 140 may include a lower capping pattern 142A and an upper capping pattern 144A on the lower capping pattern 142A.

A bit line spacer 150A may be disposed on the both side walls of each of the plurality of bit lines BL. The bit line spacer 150A may surround a bit line BL. The bit line spacer 150A may extend in the second horizontal direction Y on the both side walls of each of the plurality of bit lines BL, and a portion of the bit line spacer 150A may extend to the inside of a direct contact hole DCH to cover the upper side of a side wall of the direct contact DC. FIG. 4 illustrates that the bit line spacer 150A is a single material layer, but the bit line spacer 150A may be formed in a stacked structure of a plurality of spacer layers (not shown), and at least one of the plurality of spacer layers may be an air spacer.

The plurality of cell pad structures 130 may be disposed between each of the plurality of bit lines BL. For example, a cell pad structure 130 may be disposed at a vertical level lower than the bit lines BL between two adjacent bit lines BL. For example, an insulating pattern 152 may be disposed between two cell pad structures 130 disposed in the first horizontal direction X and between two cell pad structures 130 disposed in the second horizontal direction Y, and the insulating pattern 152 may electrically separate the two adjacent cell pad structures 130. In addition, the lower side of a portion of a side wall of a cell pad structure 130 may be in contact with the direct contact spacer DCS and the upper side of the portion of the side wall of the cell pad structure 130 may be in contact with the bit line spacer 150A. The direct contact spacer DCS and the bit line spacer 150A may be connected to each other.

The plurality of cell pad structures 130 may include a first conductive layer 132A, a first middle layer 134A, and a first metal layer 136A, which are sequentially disposed on the first active area AC1. The first conductive layer 132A may include Si, Ge, W, WN, Co, Ni, Al, Mo, Ru, Ti, TiN, Ta, TaN, or Cu, or a combination thereof. The first middle layer 134A and the first metal layer 136A may include TiN, TiSiN, W, or tungsten silicide, or a combination thereof.

As illustrated in FIG. 6, the bottom surface of the first conductive layer 132A may be disposed at a level lower than an upper surface AC1_T of the first active area AC1, and the first conductive layer 132A may be disposed to cover the upper surface AC1_T and a side wall AC1_S of the first active area AC1. Accordingly, a relatively large contact area may be secured between the first conductive layer 132A and the first active area AC1. Unlike the example illustrated in FIG. 6, the bottom surface of the first conductive layer 132A may be disposed at a level substantially the same as the upper surface AC1_T of the first active area AC1, and accordingly, the bottom surface of the first conductive layer 132A may have a flat profile.

An insulating layer 154 covering the cell pad structure 130 and the insulating pattern 152 may be disposed on the cell pad structure 130.

A plurality of insulating fences 156 may be disposed in the second horizontal direction Y between two adjacent bit lines BL. The plurality of insulating fences 156 may be disposed on the insulating layer 154 at a position at which the plurality of insulating fences 156 vertically overlaps the plurality of word line trenches 120T.

The plurality of landing pads LP may be disposed on the plurality of cell pad structures 130. Each of the plurality of landing pads LP may include a conductive barrier film 162A and a landing pad conductive layer 164A. The conductive barrier film 162A may include a titanium nitride film or a tantalum nitride film. The landing pad conductive layer 164A may include a metal, a metal nitride, or conductive polysilicon, or a combination thereof. For example, the landing pad conductive layer 164A may include W. The plurality of landing pads LP may have a plurality of island-type pattern shapes when viewed from a plane.

The plurality of landing pads LP may be electrically insulated from one another by an insulating pattern 166 surrounding the plurality of landing pads LP. The insulating pattern 166 may include at least one of a silicon nitride film, a silicon oxide film, a silicon oxynitride film, a silicon carbonitride film, or a porous film.

The insulating pattern 166 may be provided in contact with the conductive barrier film 162A. In the process of forming the insulating pattern 166, a portion of the conductive barrier film 162A may be removed. The bit line BL and the conductive barrier film 162A may be opposite to each other based on the insulating pattern 166.

The conductive barrier film 162A and the bit line BL may be provided to be spaced apart from each other based on a direction perpendicular to the stacked direction of the bit line BL and the insulating capping structure 140. For example, the conductive barrier film 162A and the bit line BL may be provided to be spaced apart from each other by a distance d. The distance d between the conductive barrier film 162A and the bit line BL may be less than the separation distance between the bit line BL and the cell pad structure 130.

A first portion of the insulating pattern 166 may be provided in contact with the insulating capping structure 140. A second portion of the insulating pattern 166 may be provided in contact with the bit line BL. At least a portion of the insulating pattern 166 may be provided in a state of being inserted into the cell pad structure 130. The upper end portion of the cell pad structure 130 may have an asymmetrical shape. The insulating pattern 166 may include a shape with a width that decreases toward the cell pad structure 130.

A landing pad LP may include the conductive barrier film 162A and the landing pad conductive layer 164A. The conductive barrier film 162A may include a barrier body 1621A provided in contact with the cell pad structure 130 and a barrier head 1622A connected to the barrier body 1621A.

The landing pad conductive layer 164A may be positioned between the insulating pattern 166 and the barrier head 1622A. At least a portion of the insulating pattern 166 may be positioned between the bit line spacer 150A and the conductive barrier film 162A. The bit line spacer 150A and the conductive barrier film 162A may be provided to be spaced apart from each other.

In the cell array area MCA, a first etching stop film 172 may be disposed on the landing pad LP and the insulating pattern 166. The capacitor structure 180 may be disposed on the first etching stop film 172. The capacitor structure 180 may include a plurality of lower electrodes 182, a capacitor dielectric layer 184, and an upper electrode 186.

The plurality of lower electrodes 182 may extend in the vertical direction Z on the plurality of landing pads LP by passing through the first etching stop film 172. The bottom portions of the plurality of lower electrodes 182 may be connected to the landing pad LP by passing through the first etching stop film 172. The capacitor dielectric layer 184 may be disposed on the plurality of lower electrodes 182. The upper electrode 186 may be disposed on the capacitor dielectric layer 184 to cover the plurality of lower electrodes 182.

The capacitor dielectric layer 184 may include at least one of a zirconium oxide, a hafnium oxide, a titanium oxide, a niobium oxide, a tantalum oxide, an yttrium oxide, a strontium titanium oxide, a barium strontium titanium oxide, a scandium oxide, and a lanthanide oxide. The lower electrode 182 and the upper electrode 186 may include at least one selected from among a metal such as ruthenium (Ru), titanium (Ti), tantalum (Ta), niobium (Nb), iridium (Ir), molybdenum (Mo), tungsten (W), and the like, a conductive metal nitride such as a titanium nitride (TiN), a tantalum nitride (TaN), a niobium nitride (NbN), a molybdenum nitride (MoN), a tungsten nitride (WN), and the like, and a conductive metal oxide such as an iridium oxide (IrO₂), a ruthenium oxide (RuO₂), and a strontium ruthenium oxide (SrRuO₃).

Each of the plurality of lower electrodes 182 may have a pillar shape extending in the vertical direction Z and may have a circular horizontal cross-section. However, the shape of the horizontal cross-section of each of the plurality of lower electrodes 182 is not limited thereto, and the plurality of lower electrodes 182 may have various polygonal and rounded polygonal horizontal cross-sections such as an elliptical shape, a quadrangular shape, a rounded quadrangular shape, a diamond shape, a trapezoidal shape, and the like. In addition, FIG. 3 illustrates an example in which the plurality of lower electrodes 182 has a pillar shape with a circular horizontal cross-section over the entire length. However, the plurality of lower electrodes 182 may also have a cylinder shape with a closed bottom.

In the peripheral circuit area PCA, the peripheral circuit transistor PTR may be disposed on the second active area AC2. The peripheral circuit transistor PTR may include a gate dielectric layer 116, a peripheral circuit gate electrode PGS, and a gate capping pattern 142B, which are sequentially stacked on the second active area AC2.

The gate dielectric layer 116 may be formed of at least one selected from among a silicon oxide film, a silicon nitride film, a silicon oxynitride film, ONO, or a high-k dielectric film having a dielectric constant higher than that of the silicon oxide film. The gate capping pattern 142B may include a silicon nitride film.

The peripheral circuit gate electrode PGS may include a second conductive layer 132B, a second middle layer 134B, and a second metal layer 136B. The second conductive layer 132B may include Si, Ge, W, WN, Co, Ni, Al, Mo, Ru, Ti, TiN, Ta, TaN, or Cu, or a combination thereof. The second middle layer 134B and the second metal layer 136B may include TiN, TiSiN, W, or tungsten silicide, or a combination thereof.

Components of the second conductive layer 132B, the second middle layer 134B, and the second metal layer 136B may be the same as components of the first conductive layer 132A, the first middle layer 134A, and the first metal layer 136A, respectively, included in the cell pad structure 130 in the cell array area MCA. For example, the peripheral circuit gate electrode PGS may be formed simultaneously during the process of forming the cell pad structure 130.

Both side walls of each of the peripheral circuit gate electrode PGS and the gate capping pattern 142B may be covered by the insulating spacer 150B. The insulating spacer 150B may include an oxide film, or a nitride film, or a combination thereof. The peripheral circuit transistor PTR and the insulating spacer 150B may be covered by a protective layer 146, and a first interlayer insulating film 148 may be disposed on the protective layer 146 such that the space between two adjacent peripheral circuit transistors PTR is filled. A capping insulating layer 144B may be disposed on the first interlayer insulating film 148 and the protective layer 146.

In the peripheral circuit area PCA, a contact plug CP may be formed in a contact hole CPH vertically passing through the first interlayer insulating film 148 and the capping insulating layer 144B. The contact plug CP may be disposed at a distance from a side surface of the peripheral circuit gate electrode PGS. The contact plug CP, like the plurality of landing pads LP formed in the cell array area MCA, may include the conductive barrier film 162B and the landing pad conductive layer 164B. A metal silicide film (not shown) may be interposed between the second active area AC2 and the contact plug CP.

When a voltage is applied to the peripheral circuit gate electrode PGS and the contact plug CP and a current is generated, capacitance may be formed on the contact plug CP adjacent to the peripheral circuit gate electrode PGS. This may be due to the effects of an electric field or other influences caused by current on the contact plug CP positioned on a side surface of the peripheral circuit gate electrode PGS. The current flowing through the contact plug CP may be influenced by the capacitance formed on the contact plug CP by the peripheral circuit gate electrode PGS.

A second etching stop film 174 covering the contact plug CP may be disposed on the capping insulating layer 144B. A second interlayer insulating film 190 covering the capacitor structure 180 may be disposed on the second etching stop film 174.

As illustrated in FIG. 4, a cell pad structure 130 disposed on the outermost side among the plurality of cell pad structures 130 may extend onto the boundary area BA. The cell pad structure 130 disposed on the boundary area BA may be referred to as a cell pad extension 130_E. The cell pad extension 130_E may include a first portion 130P1 and a second portion 130P2. The first portion 130P1 may be disposed on the first active area AC1, and the element separating film 112 and the second portion 130P2 may be disposed on the buffer layer 118. When a portion of the first metal layer 136 positioned in the peripheral circuit area PCA and the boundary area BA is not etched, the thickness of the buffer layer 118 may cause the second portion 130P2 to have an upper surface positioned at a higher level than the upper surface of the first portion 130P1.

An edge conductive layer BL_E may be disposed on the second portion 130P2 of the cell pad extension 130_E. The edge conductive layer BL_E may refer to the remaining portion after the process of patterning a bit line BL. The process of removing the edge conductive layer BL_E may be further performed, and in this case, the edge conductive layer BL_E may be omitted.

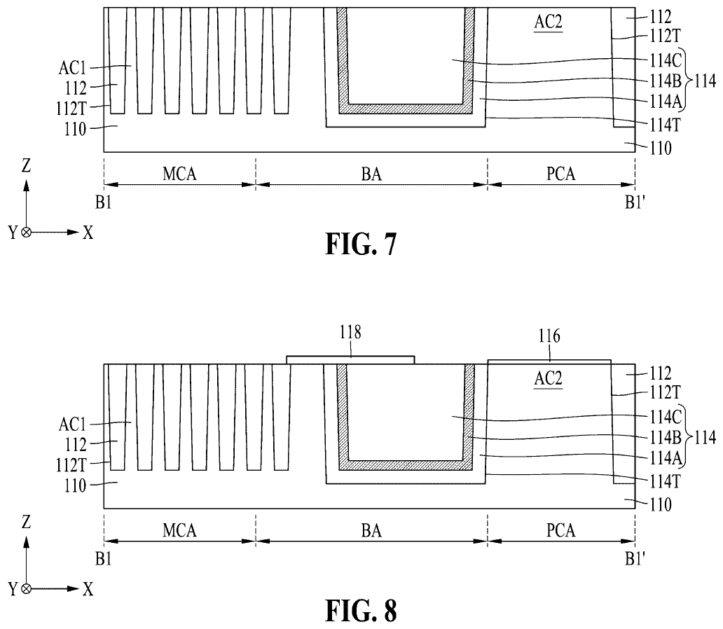

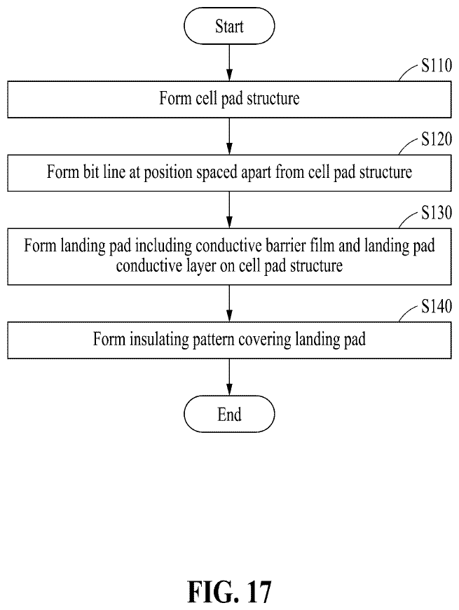

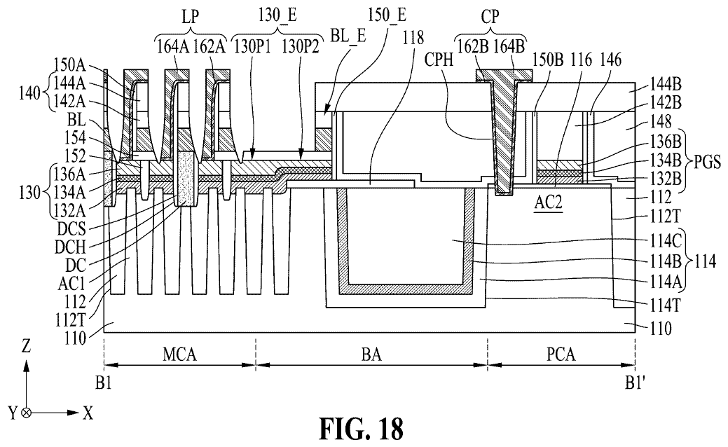

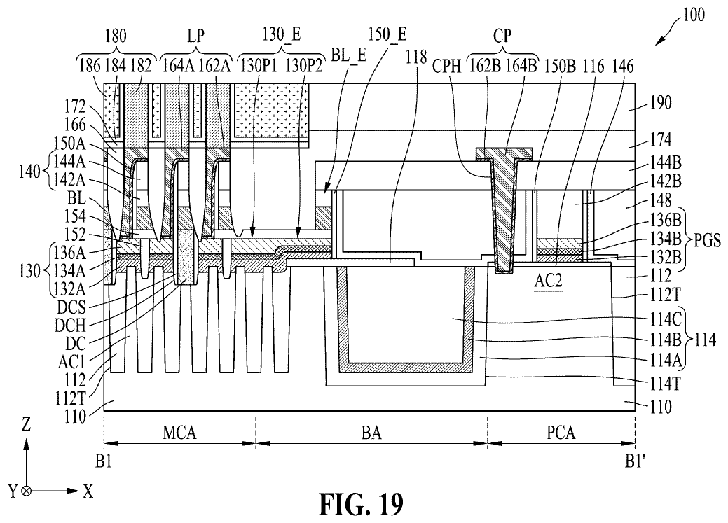

FIGS. 7 to 16 are cross-sectional views of the semiconductor device according to example embodiments and illustrate a method of manufacturing the semiconductor device. FIG. 17 is a flowchart illustrating a method of manufacturing a semiconductor memory device, according to an embodiment. FIGS. 18 and 19 are cross-sectional views of the semiconductor device according to example embodiments and illustrate the method of manufacturing the semiconductor device.

Particularly, FIGS. 7 to 16, 18, and 19 are cross-sectional views corresponding to a cross-section taken along the line B1-B1′ of FIG. 2. In FIGS. 7 to 18, the same reference numerals in FIGS. 2 to 6 refer to the same components.

Referring to FIG. 7, the plurality of element separating trenches 112T may be formed in the cell array area MCA and the peripheral circuit area PCA of the substrate 110 and the boundary trench 114T may be formed in the boundary area BA of the substrate 110.

Then, the element separating film 112 filling the plurality of element separating trenches 112T may be formed in the cell array area MCA and the peripheral circuit area PCA. By the formation of the element separating film 112, the plurality of first active areas AC1 may be defined in the cell array area MAC of the substrate 110 and a second active area AC2 may be defined in the peripheral circuit area PCA.

The element separating film 112 may be formed using a silicon oxide, a silicon nitride, or a silicon oxynitride, or a combination thereof. The element separating film 112 may be formed in a double-layer structure of a silicon oxide layer and a silicon nitride layer, but embodiments are not limited thereto.

Then, the boundary structure 114 may be formed by sequentially forming the buried insulating layer 114A, the insulating liner 114B, and the gap fill insulating layer 114C on the inner wall of the boundary trench 114T and flattening the upper portions of the buried insulating layer 114A, the insulating liner 114B, and the gap fill insulating layer 114C so that the upper surface of the substrate 110 is exposed.

The buried insulating layer 114A may be formed using a process such as an ALD process, a CVD process, a PECVD process, an LPCVD process, or the like. The process of forming the buried insulating layer 114A may be performed at the same stage as at least some stages of the process of forming the element separating film 112, but embodiments are not limited thereto. The process of forming the buried insulating layer 114A may be performed separately after the process of forming the element separating film 112 is performed.

The insulating liner 114B may be formed using a silicon nitride by a process such as an ALD process, a CVD process, a PECVD process, and an LPCVD process. The gap fill insulating layer 114C may be formed on the insulating liner 114B to fill the inside of the boundary trench 114T. The gap fill insulating layer 114C may be thick enough to completely fill the remaining portion of the inside of the boundary trench 114T.

The gap fill insulating layer 114C may include a silicon oxide such as TOSZ, USG, BPSG, PSG, FOX, PE-TEOS, or FSG.

Referring to FIG. 8, the buffer layer 118 may be formed on the cell array area MCA and the boundary area BA. The buffer layer 118 may cover the upper surface of the first active area AC1 in the cell array area MCA, and the upper surface of the second active area AC2 may not be covered by the buffer layer 118 in the peripheral circuit area PCA.

Then, the gate dielectric layer 116 may be formed on the substrate 110 in the peripheral circuit area PCA. The gate dielectric layer 116 may be formed by a process such as a thermal oxidation process, an ALD process, a CVD process, a PECVD process, and an LPCVD process.

Then, a portion of the buffer layer 118 covering the cell array area MCA may be removed, and the buffer layer 118 may remain on the boundary area BA. The buffer layer 118 may cover the upper surface of the first active area AC1 and the element separating film 112 in an edge area of the cell array area MCA and may extend onto the boundary structure 114.

By performing a recess process on the upper surface of the element separating film 112 exposed from the cell array area MCA, it may be possible to allow the upper surface of the first active area AC1 to be disposed at a level higher than the upper surface of the element separating film 112 and to allow a portion of a side wall of the first active area AC1 to be exposed. However, technical ideas of the present disclosure are not limited thereto.

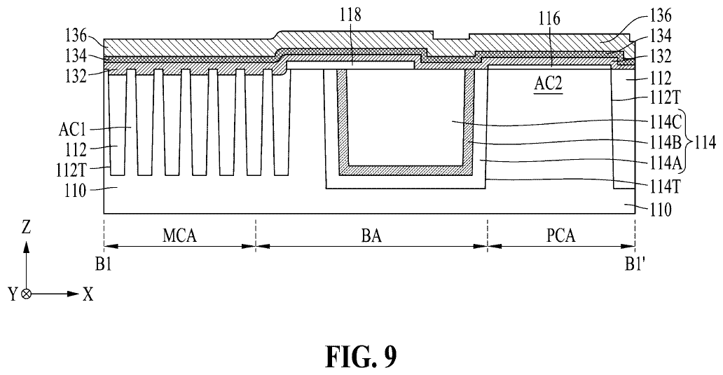

Referring to FIG. 9, a conductive layer 132 may be formed on the buffer layer 118 in the cell array area MCA and may be formed on the gate dielectric layer 116 and the element separating film 112 in the peripheral circuit area PCA. The conductive layer 132 may include Si, Ge, W, WN, Co, Ni, Al, Mo, Ru, Ti, TiN, Ta, TaN, or Cu, or a combination thereof. For example, the conductive layer 132 may include polysilicon.

Then, a middle layer 134 may be formed on the conductive layer 132 and a metal layer 136 may be formed on the middle layer 134. The middle layer 134 and the metal layer 136 may be formed on the entire area of the cell array area MCA and the peripheral circuit area PCA. The middle layer 134 and the metal layer 136 may include TiN, TiSiN, W, or tungsten silicide, or a combination thereof.

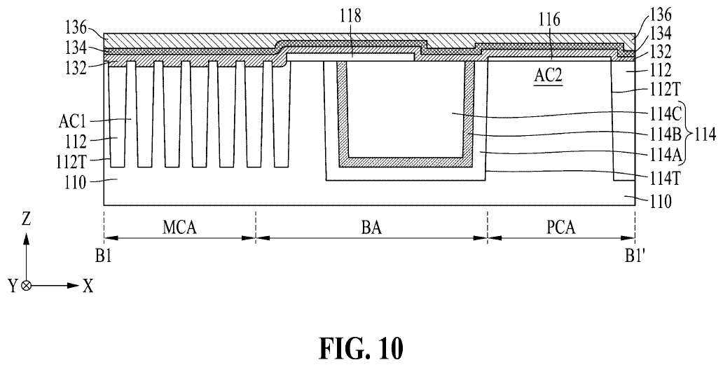

Referring to FIG. 10, a mask pattern (not shown) may be formed on the metal layer 136, and the mask pattern may be used as an etching mask. A portion of the cell array area MCA and the boundary area BA may be removed from an area that is etched by forming a mask pattern for the portion of the cell array area MCA and the boundary area BA. A portion of the metal layer 136 may be removed by etching the upper surface of the metal layer 136 formed in the peripheral circuit area PCA and at least a portion of the upper surface of the metal layer 136 formed in the boundary area BA.

As illustrated in FIG. 10, the etching of the metal layer 136 may be performed entirely on the metal layer 136 formed in the peripheral circuit area PCA and the boundary area BA.

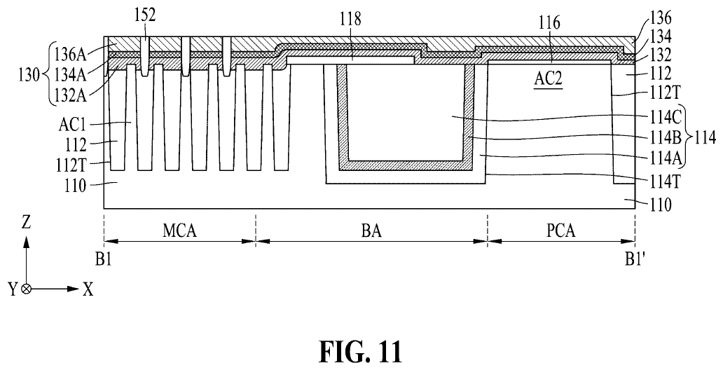

The height difference between the first portion 130P1 and the second portion 130P2 may be reduced or removed through the process of etching the metal layer 136 compared to a case without the process of etching the metal layer 136. In a process of FIG. 11, patterning difficulty of forming a cell pad structure near the boundary area BA may be reduced through the process of etching the metal layer 136. As the vertical height of the metal layer 136 is reduced, the difficulty of patterning the metal layer 136, the middle layer 134, and the conductive layer 132 in the cell array area MCA and forming the plurality of cell pad structures 130 may be reduced.

Referring to FIG. 11, the plurality of cell pad structures 130 may be formed by forming a mask pattern (not shown) on the metal layer 136 and patterning the metal layer 136, the middle layer 134, and the conductive layer 132 in the cell array area MCA using the mask pattern as an etching mask.

The plurality of cell pad structures 130 may have a matrix arrangement, spaced apart along the first horizontal direction X and the second horizontal direction Y The metal layer 136 may remain on the peripheral circuit area PCA.

A cell pad structure 130 disposed on the outermost side among the plurality of cell pad structures 130 may extend onto the boundary area BA. The cell pad structure 130 disposed on the boundary area BA may be referred to as the cell pad extension 130_E. The cell pad extension 130_E may include the first portion 130P1 and the second portion 130P2. The first portion 130P1 may be disposed on the first active area AC1 and the element separating film 112, and the second portion 130P2 may be disposed on the buffer layer 118. Due to the thickness of the buffer layer 118, the upper surface of the second portion 130P2 may be disposed at a level higher than the upper surface of the first portion 130P1.

Then, the insulating pattern 152 surrounding the side walls of the plurality of cell pad structures 130 may be formed. The insulating pattern 152 may be formed using a silicon nitride.

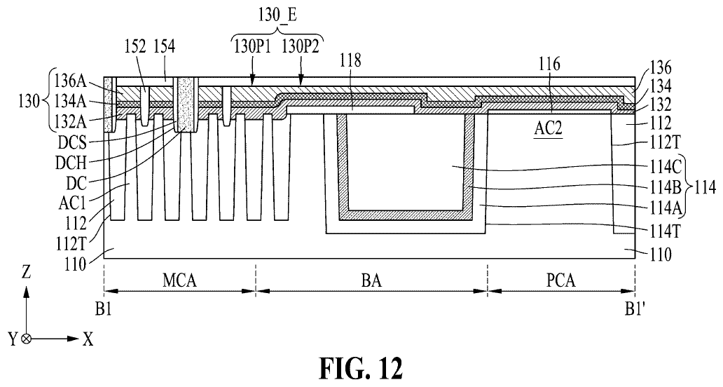

Referring to FIG. 12, the insulating layer 154 may be formed on the upper surface of the plurality of cell pad structures 130 and the insulating pattern 152 and on the metal layer 136. The insulating layer 154 may be formed using a silicon nitride.

Then, a mask pattern (not shown) may be formed on the insulating layer 154, and the first active area AC1 of the substrate 110 may be exposed again by removing some cell pad structures 130 of the plurality of cell pad structures 130. Then, a direct contact hole DCH may be formed by further removing a portion of the upper side of the exposed substrate 110.

Subsequently, a direct contact spacer DCS may be formed on the inner wall of the direct contact hole DCH. For example, the direct contact spacer DCS may be formed using a silicon nitride or a silicon oxide.

A direct contact DC may be formed in the direct contact hole DCH by forming a conductive layer (not shown) in the direct contact hole DCH and performing etchback on the upper portion of the conductive layer so that the upper surface of the insulating layer 154 is exposed.

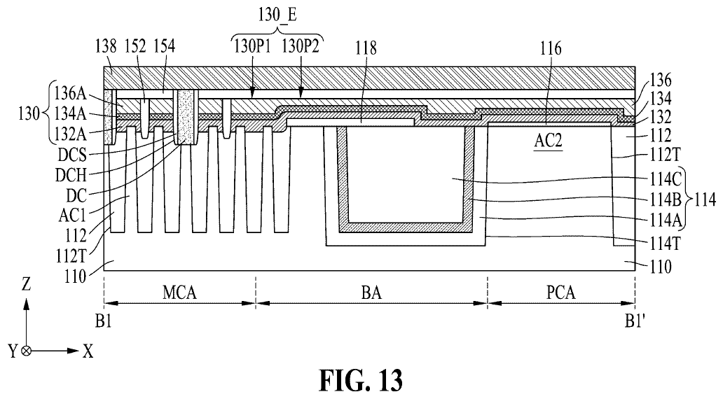

Referring to FIG. 13, a bit line conductive layer 138 covering the direct contact DC and the insulating layer 154 may be formed. The bit line conductive layer 138 may include at least one of ruthenium (Ru), tungsten (W), cobalt (Co), titanium (Ti), and a titanium nitride (TiN).

The bit line conductive layer 138 may be formed using a material that is different from a material included in the metal layer 136. However, embodiments are not limited thereto, and the bit line conductive layer 138 may be formed using the same material as the material included in the metal layer 136.

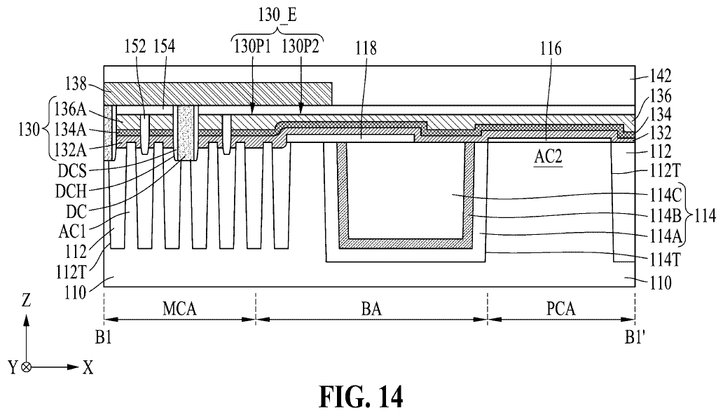

Referring to FIG. 14, the insulating layer 154 and the bit line conductive layer 138 may be removed from the peripheral circuit area PCA and the boundary area BA. Then, the first insulating capping layer 142 may be formed on the metal layer 136 in the peripheral circuit area PCA and on the bit line conductive layer 138 in the cell array area MCA.

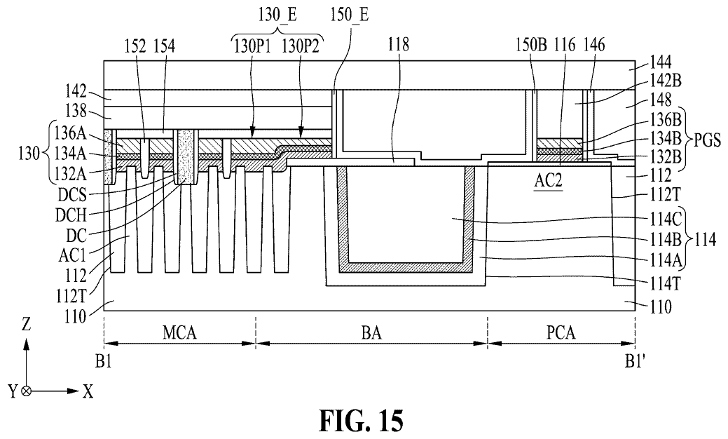

Referring to FIG. 15, a mask pattern (not shown) may be formed on the first insulating capping layer 142, and the gate capping pattern 142B and the peripheral circuit gate electrode PGS may be formed by patterning the first insulating capping layer 142, the metal layer 136, the middle layer 134, and the conductive layer 132 using the mask pattern in the peripheral circuit area PCA.

The peripheral circuit gate electrode PGS may include the second conductive layer 132B, the second middle layer 134B, and the second metal layer 136B, which are sequentially disposed on the gate dielectric layer 116.

Then, the insulating spacer 150B covering a side wall of the peripheral circuit gate structure PG may be formed. The insulating spacer 150B may be formed using a silicon nitride.

In the process of forming the insulating spacer 150B, a spacer 150_E may also be disposed on a side wall of the cell pad extension 130_E disposed in the boundary area BA.

Subsequently, the protective layer 146 covering a side wall of the gate capping pattern 142B and the peripheral circuit gate electrode PGS. An insulating layer (not shown) may be formed on the protective layer 146 to completely cover the capping pattern 142B and the peripheral circuit gate electrode PGS, and the first interlayer insulating film 148 may be formed by flattening the upper portion of the insulating layer so that the upper surface of the gate capping pattern 142B is exposed.

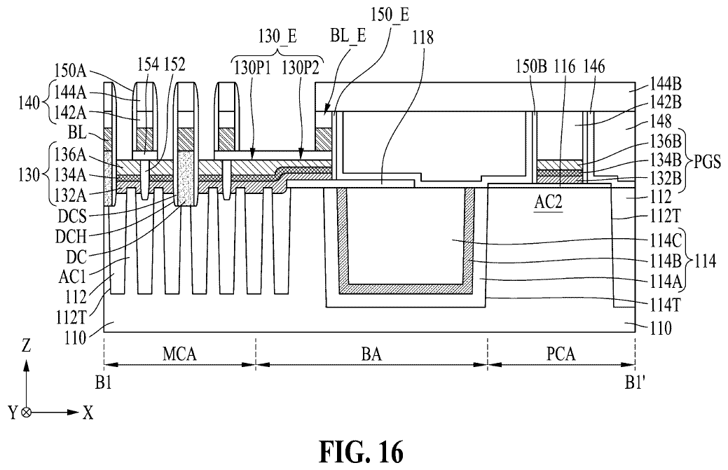

Referring to FIG. 16, the second insulating capping layer 144 may be formed on the first insulating capping layer 142 in the cell array area MCA and on the first interlayer insulating film 148 in the peripheral circuit area PCA.

Then, the plurality of insulating capping structures 140 and the plurality of bit lines BL may be formed by patterning the second insulating capping layer 144, the first insulating capping layer 142, and the bit line conductive layer 138 in the cell array area MCA.

In the process of forming a bit line BL, a portion of the upper side of the direct contact spacer DCS disposed in the direct contact hole DCH may be removed together, and the upper surface of the direct contact spacer DCS may be disposed at a level lower than the upper surface of the direct contact DC.

In the process of forming the bit line BL, a portion of the bit line conductive layer 138 may remain on the boundary area BA, and this portion may be referred to as the edge conductive layer BL_E.

Subsequently, the bit line spacer 150A may be formed on a side wall of the bit line structure BLS, and the plurality of insulating fences 156 may be formed between each of the plurality of bit lines BL.

Referring to FIG. 17, a method of manufacturing a semiconductor device may include operation S110 of forming a cell pad structure; operation S120 of forming a bit line at a position spaced apart from a cell pad structure; operation S130 of forming, on the cell pad structure, a landing pad including a conductive barrier film and a landing pad conductive layer; and operation S140 of forming an insulating pattern covering the landing pad.

In operation S140 of forming the insulating pattern, at least a portion of the conductive barrier film 162A may be removed. In operation S140 of forming the insulating pattern, a portion of a bit line BL may be removed. The bit line BL and the conductive barrier film 162A may be opposite to each other based on an insulating pattern 166.

Referring to FIG. 18, a plurality of contact holes CPH exposing the second active area AC2 of the substrate 110 may be formed by etching the second insulating capping layer 144 and the first interlayer insulating film 148 in the peripheral circuit area PCA. Then, the upper surface of the cell pad structure 130 may be exposed by removing the insulating layer 154 exposed between bit lines BL in the cell array area MCA.

Subsequently, the plurality of landing pads LP including the conductive barrier film 162A and the landing pad conductive layer 164A may be formed in the cell array area MCA, and the plurality of contact plugs CP including the conductive barrier film 162B and the landing pad conductive layer 164B may be formed in the peripheral circuit area PCA.

Referring to FIG. 19, the insulating pattern 166 covering the plurality of landing pads LP may be formed in the cell array area MCA, and the second etching stop film 174 covering the plurality of contact plugs CP may be formed in the peripheral circuit area PCA.

Then, the first etching stop film 172 may be formed in the cell array area MCA.

The capacitor structure 180 may be disposed on the first etching stop film 172. The capacitor structure 180 may include a plurality of lower electrodes 182, the capacitor dielectric layer 184, and the upper electrode 186. The plurality of lower electrodes 182 connected to the landing pad LP by passing through the first etching stop film 172 may be formed, and the capacitor dielectric layer 184 and the upper electrode 186 may be sequentially formed on side walls of the plurality of lower electrodes 182. Then, the second interlayer insulating film 190 covering the upper electrode 186 may be formed on the cell array area MCA and the peripheral circuit area PCA.

The semiconductor device 100 may be completed by performing the method described above.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As described above, although the examples have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents of the claims are within the scope of the following claims.

What is claimed is:

1. A semiconductor device comprising:
a substrate including a cell array area and a peripheral area;
a plurality of bit lines in the cell array area;
a plurality of insulating capping structures covering the plurality of bit lines;
a plurality of bit line spacers surrounding the plurality of bit lines;
a cell pad structure between a pair of adjacent bit lines among the plurality of bit lines;
a landing pad on the cell pad structure, the landing pad including a conductive barrier film and a landing pad conductive layer; and
an insulating pattern covering at least a portion of the landing pad, the insulating pattern being in contact with the conductive barrier film.

2. The semiconductor device of claim 1, wherein
a bit line among the plurality of bit lines and the conductive barrier film are opposite to each other with the insulating pattern therebetween.

3. The semiconductor device of claim 1, wherein
a bit line among the plurality of bit lines and the conductive barrier film are spaced apart from each other in a direction perpendicular to a stacking direction of the bit line and a corresponding one of the plurality of insulating capping structures.

4. The semiconductor device of claim 1, wherein the insulating pattern is in contact with a corresponding one of the plurality of insulating capping structures.

5. The semiconductor device of claim 4, wherein the insulating pattern is in contact with a corresponding one of the plurality of bit lines.

6. The semiconductor device of claim 1, wherein the conductive barrier film comprises:
a barrier body in contact with the cell pad structure; and
a barrier head connected to the barrier body.

7. The semiconductor device of claim 6, wherein the landing pad conductive layer is between the insulating pattern and the barrier head.

8. The semiconductor device of claim 1, wherein at least a portion of the insulating pattern is between the bit line spacer and the conductive barrier film.

9. The semiconductor device of claim 8, wherein the bit line spacer and the conductive barrier film are spaced apart from each other.

10. The semiconductor device of claim 1, wherein the conductive barrier film comprises a titanium nitride film or a tantalum nitride film.

11. The semiconductor device of claim 1, wherein the insulating pattern comprises a silicon nitride film, a silicon oxide film, a silicon oxynitride film, a silicon carbonitride film, or a porous film.

12. The semiconductor device of claim 1, wherein at least a portion of the insulating pattern is in the cell pad structure.

13. The semiconductor device of claim 1, wherein an upper end portion of the cell pad structure has an asymmetrical shape.

14. The semiconductor device of claim 1, wherein
a distance between a bit line among the plurality of bit lines and the cell pad structure is less than a distance between the bit line and the conductive barrier film, based on a direction perpendicular to a stacking direction of the plurality of insulating capping structures and the plurality of bit lines.

15. The semiconductor device of claim 1, wherein a width of the insulating pattern decreases toward the cell pad structure.

16. A method of manufacturing a semiconductor device, the method comprising:
forming a cell pad structure;
forming a bit line at a position spaced apart from the cell pad structure;
forming a landing pad including a conductive barrier film and a landing pad conductive layer on the cell pad structure; and
forming an insulating pattern covering the landing pad,
wherein the forming the insulating pattern includes removing at least a portion of the conductive barrier film.

17. The method of claim 16, wherein the bit line and the conductive barrier film are opposite each other based with the insulating pattern therebetween.

18. The method of claim 16, wherein the forming the insulating pattern includes forming a portion of the insulating pattern in the cell pad structure.

19. The method of claim 16, wherein the forming the insulating pattern includes removing a portion of the bit line.

20. A semiconductor device comprising:
a substrate including a cell array area and a peripheral area;
a plurality of bit lines in the cell array area;
a plurality of insulating capping structures covering the plurality of bit lines;
a cell pad structure between a pair of adjacent bit lines among the plurality of bit lines;
a landing pad in the cell pad structure, the landing pad including a conductive barrier film and a landing pad conductive layer; and
an insulating pattern covering at least a portion of the landing pad and overlapping the cell pad structure in a direction perpendicular to a stacking direction of the plurality of bit lines and the plurality of insulating capping structures.
